(19) United States
(12) Patent Application Publication
(10) Pub. No.: US 2004/0155268 A1
(43) Pub. Date: Aug. 12, 2004

(54) Method and apparatus for improving the electrical resistance of conductive paths

(75) Inventors: Werner Robl, Regensburg (DE); Roy Iggulden, Newburgh, NY (US); Padraic Shafer, Fishkill, NY (US); Keith Kwong Hon Wong, Wappingers Falls, NY (US)

Correspondence Address: LERNER, DAVID, LITTENBERG,, KRUMHOLZ & MENTLIK, 600 SOUTH AVENUE WEST, WESTFIELD, NJ, 07090, US

(73) Assignees: Infineon Technologies North America Corp., San Jose, CA; International Business Machines Corporation, Armonk, NY

(21) Appl. No.: 10/359,366

(22) Filed: Feb. 6, 2003

(51) Int. Cl. H01L 21/8242; H01L 29/76; H01L 31/062; H01L 21/4763; H01L 31/119

(52) U.S. Cl. 257/288; 438/585; 438/592; 257/412

(57) ABSTRACT

Methods and apparatus in accordance with the present invention may employ a layer of tungsten nitride having a ratio of nitrogen to tungsten that is below about 0.7 at and a layer of tungsten formed on the layer of tungsten nitride to obtain a conductive material.

### BACKGROUND OF THE INVENTION

The present invention relates to methods and apparatus for improving the electrical resistance of conductive paths in integrated circuits.

Conductive paths are used to interconnect various nodes within an integrated circuit. The resistance of these conductive paths can affect the electrical performance of the integrated circuit, sometimes in disadvantageous ways. For example, the electrical resistance of certain conductive paths in dynamic random access memory (DRAM) arrays can severely impact the speed at which information can be written to and read from memory. More particularly, FIG. 1 is a schematic diagram of a conventional array of storage cells 22 contained within a conventional DRAM array. Each storage cell 22 includes a single array transistor 24 and a single capacitor 26. A given storage cell 22 of the memory array 12 may be accessed by activating a particular bit line and word line. As the storage cells 22 of the memory array 12 are arranged in a grid, only one cell 22 will be accessed for a given combination of word line and bit line activation.

For example, in order to write a data bit into storage cell (0, 1), word line 0 is activated by applying an appropriate voltage to that line, e.g., a logic high (such as 3.3 V, 5 V, 15 V, etc.) or a logic low (such as 0 V). The appropriate voltage on word line 0 will turn on each of the array transistors 24 connected to that line including the array transistor 24 of cell (0, 1). A voltage may then be presented on bit line 1, which will charge the capacitor 26 of cell (0, 1) to a desired level, e.g., a logic high or logic low consistent with the data bit. The voltage may be presented on bit line 1 (and/or any of the other bit lines) by way of a suitably connected data bus. When the voltage on word line 0 is removed, the array transistor 24 of cell (0, 1) is biased off and the charge on the capacitor 26 of the cell (0, 1) is stored.

Reading a data bit from a particular storage cell 22, such as cell (0, 1), is substantially similar to writing a data bit except that the voltage on bit line 1 is imposed by the capacitor 26 of the storage cell 22 rather than by the data bus. Typically, a single storage cell 22 is not written to or read from; rather, an entire word (series of data bits) is written into the memory array 12 or read from the memory array 12 by applying the appropriate voltage on a particular word line and either imposing or sensing voltage on each of the bit lines, e.g., bit lines 0, 1, 2, etc.

Irrespective of whether data are being written into or read from the capacitors 26 of the array 12, the transistors 24 associated with the capacitors 26 must be biased on. As discussed above, this entails applying a voltage to the gates with respect to the sources of the transistors 24. The speed at which the transistors 24 may be biased on (or biased off) is affected by the electrical resistance of the conductive paths forming the word lines, which are coupled to the gates of the transistors 24. This is so because there is an inherent series capacitance associated with each gate of the transistors 24, which capacitance forms a time constant with the equivalent series resistance associated with the respective word line. The speed at which the transistors 24 turn on and off is also affected by the electrical resistance of the conductive paths forming the bit lines because the total resistance affecting the time constant associated with the gate capacitance is a function of the respective resistances of the word line and bit line.

Efforts to reduce the time constant associated with the capacitors 24 have focused on reducing the gate capacitance and/or reducing the total resistance in series with such gate capacitance. It connection with reducing the total resistance, some efforts have focused on utilizing a low resistive material in forming the conductive paths associated with the word lines, bit lines and gate materials (i.e., the gate stack metalization). Depending on the type of materials used to form the gate stack metalization, annealing is sometimes required in order to achieve relatively low electrical resistances. Unfortunately, the annealing process requires subjecting the integrated circuit to elevated temperatures for extended periods of time, which uses a corresponding amount of the thermal budget permitted for the integrated circuit production process.

Accordingly, there are needs in the art for methods and apparatus for reducing the electrical resistance associated with conductive paths in integrated circuits, such as DRAM circuits, preferably methods and apparatus that do not have significant impacts on the overall thermal budget of the integrated circuit process.

### SUMMARY OF THE INVENTION

In accordance with one or more aspects of the present invention, a method includes the formation of a layer of tungsten on a layer of tungsten nitride to produce a conductive path in an integrated circuit, wherein the ratio of nitrogen to tungsten in the tungsten nitride layer is below about 0.7 at. The method may further include forming a layer of silicon-nitride, tungsten nitride, silicon oxide, or any other insulating layer on the layer of tungsten in order to protect the layer of tungsten from deterioration or to be used as a hardmask for gate stack patterning.

By way of example, the tungsten nitride layer may be formed on a layer of polysilicon in order to form a gate stack of a field effect transistor, wherein the gate stack includes the polysilicon layer, the tungsten nitride layer, the tungsten layer and the silicon-nitride layer (or tungsten nitride) layer.

The layer of tungsten nitride may be formed on the layer of polysilicon using a physical vapor deposition technique, such as sputtering. More particularly, the method may include forming a mixture of argon gas and nitrogen gas, and targeting a sample of tungsten with the mixture of argon gas and nitrogen gas in the presence of the polysilicon. The ratio of nitrogen to tungsten in the layer of tungsten nitride may be achieved by controlling the ratio of the argon gas and the nitrogen gas. Other deposition techniques may be employed such as chemical vapor deposition, atomic layer deposition, etc.

When the above method is applied to the formation of a DRAM array, an advantageously low gate stack resistance may be achieved by insuring that the ratio of nitrogen to tungsten in the tungsten nitride layer is below about 0.7 at.

Other aspects, features, advantages, etc., will become apparent to one skilled in the art in view of the description herein taken in conjunction with the accompanying drawings.

### BRIEF DESCRIPTION OF THE DRAWINGS

For the purposes of illustrating the invention, there are shown in the drawings forms that are presently preferred, it being understood, however, that the invention is not limited to the precise arrangements and/or instrumentalities shown.

FIG. 1 is a schematic diagram illustrating a conventional circuit topology employed in forming memory arrays in accordance with the prior art;

FIG. 2 is a side elevational view of a memory cell in accordance with the present invention;

FIG. 3 is a data table illustrating certain information obtained by testing conductive paths formed using the methods and apparatus of the present invention; and

FIG. 4 is a graph showing certain of the information contained in FIG. 3.

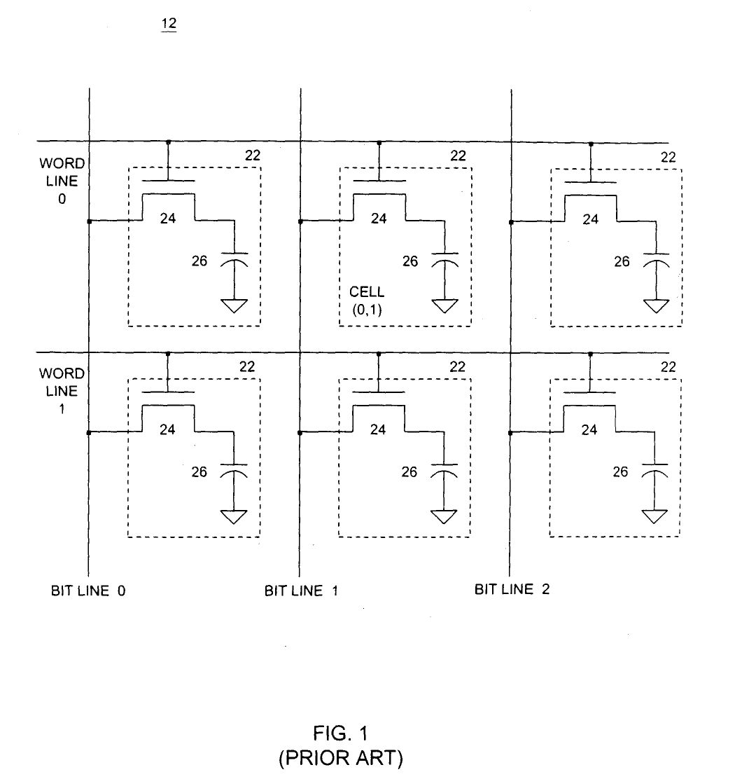

### DETAILED DESCRIPTION OF THE PREFERRED EMBODIMENTS

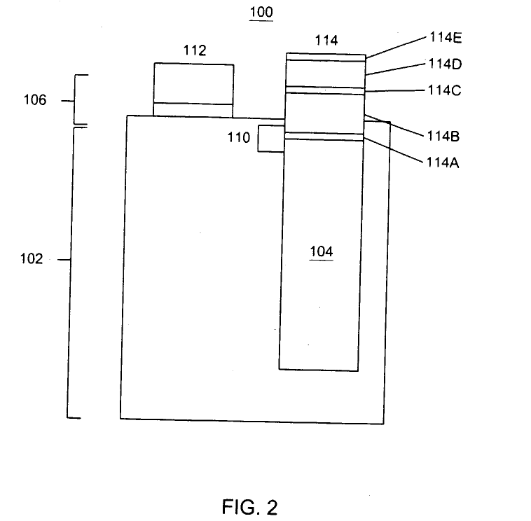

Referring now to the drawings wherein like numerals indicate like elements, there is shown in FIG. 2 a side elevational view of a memory cell 100 in accordance with one or more aspects of the present invention. The memory cell 100 generally includes a substrate 102, a trench capacitor 104 formed within the substrate 102, and an array transistor 106 formed above the trench capacitor 104. The material and processes described herein can be employed with various kinds of substrate 102, including, silicon (Si), gallium arsenide (gaAs), indium phosphide (InP) and silicon carbide (SiC).

The array transistor 106 includes a drain 110 that, for example, may be formed by way of a buried strap. The array transistor 106 also includes a source 112 and a gate 114. The gate 114 preferably comprises a gate stack including a number of layers 114A-114D. These layers include an insulation layer 114A, a polysilicon layer 114B and metalization layers 114C and 114D. An optional additional layer 114E is also contemplated.

The metalization layers 114C and 114D are preferably formed from tungsten nitride (WN) and substantially pure tungsten (W), respectively. The tungsten nitride layer 114C preferably provides a barrier between the tungsten layer 114D and the underlying polysilicon layer 114B. This barrier prevents any disadvantageous reaction between the tungsten layer 114D and the polysilicon layer 114B (such as forming a tungsten-silicide, which creates a high resistance). It is noted that utilizing a relatively low resistive gate material, such as tungsten, has the advantageous property of lowering the electrical resistance and the overall capacitance of the gate stack. While the electrical resistance is reduced by the tungsten material itself, the capacitance may also be reduced by taking advantage of the low electrical resistance and lowering the gate stack height.

In accordance with one or more further aspects of the present invention, the ratio of nitrogen to tungsten within the tungsten nitride layer 114C is preferably below about 0.7 at. It is noted the ratio of nitrogen to tungsten of 0.7 at equals 0.43 at %. It has been found that rather unexpected and advantageous results are obtained when this ratio is utilized. For example, the electrical resistance of the gate stack attains a relatively low value prior to annealing. Moreover, the level of electrical resistance may be sufficiently low to obviate the necessity for annealing altogether, thereby eliminating the need to utilize a portion of the overall thermal budget for the annealing process.

An optional layer 114E of silicon-nitride, tungsten nitride, silicon oxide, or any other insulating layer may be disposed on the tungsten layer 114D in order to protect the tungsten layer 114D from deterioration or for use as a hardmask for gate stack patterning.

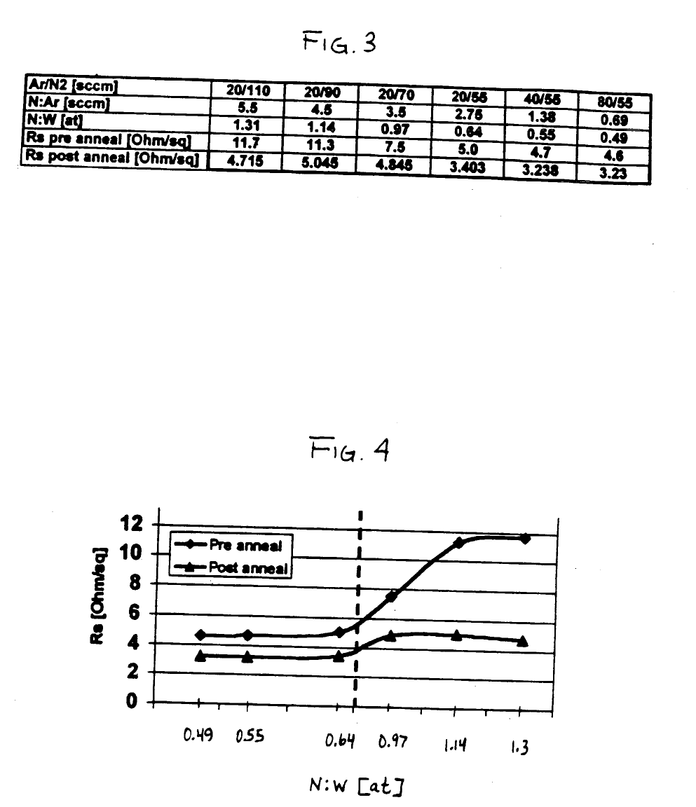

The advantageous affects of the present invention will be better appreciated with reference to FIGS. 3 and 4, which illustrate certain experimental data obtained by testing conductive material formed in accordance with the methods and apparatus of the present invention. While the present invention is not limited by any theory of operation, the process of sputtering was utilized in order to produce the conductive material for experimentation. Indeed, while sputtering falls within the broader class of physical vapor deposition processes, any of the known processes (e.g., chemical vapor deposition, atomic layer deposition, etc.) or hereinafter developed processes in order to produce the conductive material are considered within the scope of the present invention.

By way of example and not by way of limitation, a standard sputtering production tool, called AMAT Endura, was utilized to produce conductive materials having various ratios of nitrogen to tungsten. More particularly, a mixture of argon gas and nitrogen gas was formed and a sample of substantially pure tungsten was targeted with the mixture in the presence of polysilicon to form a layer of tungsten nitride on the polysilicon. The flows of argon and nitrogen gas were applied utilizing the standard cc per minute (sccm) process. Various samples of conductive material having varying tungsten nitride stoichiometry were obtained by varying the relative flows of the argon gas and the nitrogen gas.

FIG. 3 is a table containing a tabulation of certain data including a ratio of argon gas and nitrogen gas (Ar/N2, or N:Ar), a ratio of nitrogen to tungsten (N:W), pre-annealing resistance (Rs) and post-annealing resistance (Rs). The varying flows of argon gas and nitrogen gas include 20/110 Ar/N2 (5.5 N:Ar), 20/90 (4.5), 20/70 (3.5), 20/55 (2.75), 40/55 (1.38) and 80/55 (0.69). These gas flows yielded conductive materials having respective tungsten nitride layers of differing ratios including 1.31 (N:W at), 1.14, 0.97, 0.64, 0.55 and 0.49, respectively.

For the purposes of experimentation, the thickness of the tungsten nitride layer was about 4 nm and the thickness of the substantially pure tungsten layer was about 35 nm. The sheet resistances of the conductive materials were measured using a 4-point probe to obtain pre-annealing resistance, Rs. The samples of conductive material were then annealed in an argon ambient environment at 1050° C. for 10 seconds. The sheet resistance of the conductive materials were measured to obtain post-annealing resistance.

The composition of the tungsten nitride layers were measured utilizing the well-known RBS process utilizing pure tungsten nitride films of 40 nm thickness.

While FIG. 3 tabulates the pre-annealing and post-annealing resistances, FIG. 4 graphically illustrates these data. In FIG. 4, the ordinate axis represents the sheet resistance, Rs, measured pre-anneal and post-anneal, while the abscissa axis represents the ratio of nitrogen to tungsten in the tungsten nitride layer. As can be seen from FIG. 4, the pre-anneal and post-anneal sheet resistances at ratios of nitrogen to tungsten above about 0.7 at are rather significant, reaching 11.7 versus 4.7 at a ratio of 1.3 at. In contrast, the differences between the pre-anneal and post-anneal sheet resistances at ratios below about 0.7 at are relatively insignificant, for example 4.6 versus 3.2 at a ratio of 0.49 at. Moreover, the pre-anneal sheet resistance of 5.0 obtained by a sample having a ratio of 0.64 nitrogen to tungsten is about the same as the post-anneal sheet resistance of 4.85 for a conductive material having a ratio of 0.97 nitrogen to tungsten.

Advantageously, the discovery that desirable resistance properties of a conductive material employing a tungsten nitride layer may be obtained by insuring that the ratio of nitrogen to tungsten is below about 0.7 at permits improved performance and possibly elimination of the annealing step. When utilizing the present invention in the context of a DRAM array, faster data reading and writing performance may be enjoyed by virtue of lower metalization resistance and, in at least some cases, such lower resistance may be achieved without the need to anneal the metalization, thereby avoiding the need to use a portion of the thermal budget during the integrated circuit fabrication.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method, comprising:
forming a layer of tungsten nitride such that the ratio of nitrogen to tungsten is below about 0.7 at; and
forming a layer of tungsten onto the layer of tungsten nitride.

2. The method of claim 1, further comprising forming an insulating layer on the layer of tungsten.

3. The method of claim 2, wherein the insulating layer is formed from tungsten nitride, silicon nitride, or silicon oxide.

4. The method of claim 1, further comprising forming the layer of tungsten nitride onto a layer of polysilicon to form a gate stack of a field effect transistor.

5. The method of claim 4, further comprising sputtering the layer of tungsten nitride onto the layer of polysilicon to form the gate stack.

6. The method of claim 5, further comprising:
forming a mixture of argon gas and nitrogen gas; and
targeting a sample of tungsten with the mixture of argon gas and nitrogen gas in the presence of the polysilicon to form the layer of tungsten nitride on the polysilicon,
wherein the ratio of nitrogen to tungsten is achieved by controlling a ratio of the argon gas and the nitrogen gas.

7. A method, comprising:
forming a layer of tungsten nitride onto a layer of polysilicon, wherein the ratio of nitrogen to tungsten is below about 0.7 at;
forming a layer of tungsten onto the layer of tungsten nitride; and
forming a layer of nitride on the layer of tungsten to form a gate stack of a field effect transistor.

8. The method of claim 7, further comprising sputtering the layer of tungsten nitride onto the layer of polysilicon.

9. The method of claim 8, further comprising:
forming a mixture of argon gas and nitrogen gas; and
targeting a sample of tungsten with the mixture of argon gas and nitrogen gas in the presence of the polysilicon to form the layer of tungsten nitride on the polysilicon,
wherein the ratio of nitrogen to tungsten is achieved by controlling a ratio of the argon gas and the nitrogen gas.

10. A method, comprising:
forming a trench capacitor in a substrate; and
forming an access transistor coupled to the trench capacitor, wherein a gate stack of the access transistor is produced by: forming a layer of tungsten nitride onto a layer of polysilicon, wherein the ratio of nitrogen to tungsten is below about 0.7 at; forming a layer of tungsten onto the layer of tungsten nitride; and forming a layer of nitride on the layer of tungsten to form the gate stack.

11. An apparatus, comprising:
a layer of tungsten nitride having a ratio of nitrogen to tungsten below about 0.7 at; and
a layer of tungsten on the layer of tungsten nitride.

12. The apparatus of claim 11, further comprising an insulted layer on the layer of tungsten.

13. The apparatus of claim 12, wherein the insulating layer is formed from tungsten nitride, silicon nitride, or silicon oxide.

14. The apparatus of claim 11, further comprising a layer of polysilicon onto which the layer of tungsten nitride is formed to produce a gate stack of a field effect transistor.

15. An apparatus, comprising:
a trench capacitor in a substrate; and
an access transistor coupled to the trench capacitor, the access transistor having a gate stack including:
a layer of polysilicon;
a layer of tungsten nitride on the layer of polysilicon, wherein the ratio of nitrogen to tungsten is below about 0.7 at;
a layer of tungsten on the layer of tungsten nitride; and
a layer of nitride on the layer of tungsten.
